(19) United States
(12) Patent Application Publication
(10) Pub. No.: US 2026/0282547 A1
(43) Pub. Date: Sep. 17, 2026

(54) DISPLAY PANEL AND ELECTRONIC DEVICE INCLUDING THE SAME

(71) Applicant: Samsung Display Co., Ltd., Yongin-si (KR)

(72) Inventors: DONGWOO KIM, Yongin-si (KR); KYUNG-BAE KIM, Yongin-si (KR); YEONKYUNG KIM, Yongin-si (KR); YONGHEE LEE, Yongin-si (KR)

(21) Appl. No.: 19/541,456

(22) Filed: Feb. 17, 2026

(30) Foreign Application Priority Data
Mar. 11, 2025 (KR) 10-2025-0031245

(51) Int. Cl. H10D 86/60

(52) U.S. Cl. CPC H10D 86/60

(57) ABSTRACT

A display panel includes: a circuit layer including a pixel driving circuit part including: a first transistor which is a driving transistor, a second transistor which operates in response to a first gate signal, a third transistor which operates in response to a second gate signal, a fourth transistor which operates in response to a third gate signal, a first initialization transistor which operates in response to a first initialization gate signal and is an NMOS transistor, a second initialization transistor which operates in response to a second initialization gate signal and is an NMOS transistor, and a capacitor, and a light-emitting element disposed on the circuit layer.

This application claims priority to Korean Patent Application No. 10-2025-0031245, filed on Mar. 11, 2025, and all the benefits accruing therefrom under 35 U.S.C. § 119, the content of which in its entirety is herein incorporated by reference.

### BACKGROUND

### 1. Technical Field

Embodiments provide generally to a display device and an electronic device including the same. More particularly, embodiments relate to the display panel which provides visual information and an electronic device including the same.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

Recently, display devices using high-resolution micro OLEDs are being manufactured. The high-resolution micro OLEDs may be OLEDos (organic light-emitting diodes on silicon) formed using a semiconductor process based on a silicon wafer.

### SUMMARY

Embodiments provide a display panel capable of displaying high-resolution images.

Embodiments provide an electronic device including the display panel.

A display panel according to embodiments of the present disclosure includes a circuit layer including a pixel driving circuit part including: a first transistor including a gate electrode connected to a first node, a first electrode which receives a first power voltage, and a second electrode connected to a second node, a second transistor including a gate electrode which receives a first gate signal, a first electrode which receives a date voltage, and a second electrode connected to a third node, a third transistor including a gate electrode which receives a second gate signal, a first electrode connected to the first node, and a second electrode connected to the second node, a fourth transistor including a gate electrode which receives an emission control signal, a first electrode connected to the second node, and a second electrode connected to a fourth node, a first initialization transistor, which is an N-channel Metal-Oxide-Semiconductor (NMOS) transistor, includes a gate electrode which receives a first initialization gate signal, a first electrode which receives an initialization voltage, and a second electrode connected to the fourth node, a second initialization transistor, which is an NMOS transistor, includes a gate electrode which receives a second initialization gate signal, a first electrode which receives a pre-charging voltage, and a second electrode connected to the first node, and a capacitor connected between the third node and the first node, and a light-emitting element disposed on the circuit layer and including an anode electrode connected to the fourth node and a cathode electrode which receives a second power voltage.

In an embodiment, the circuit layer may further include a first insulating layer disposed on a silicon wafer substrate and a second insulating layer disposed on the first insulating layer, the first transistor, the second transistor, the third transistor, and the fourth transistor may be formed in and on the silicon wafer substrate, and the first initialization transistor and the second initialization transistor may be disposed on the first insulating layer.

In an embodiment, the NMOS transistors of the first initialization transistor and the second initialization transistor may include oxide semiconductors.

In an embodiment, the first transistor, the second transistor, the third transistor, and the fourth transistor may be P-channel Metal-Oxide-Semiconductor (PMOS) transistors.

In an embodiment, the PMOS transistors of the first transistor, the second transistor, the third transistor, and the fourth transistor may be formed in and on a silicon wafer substrate.

In an embodiment, the pixel driving circuit part may further include a third initialization transistor including a gate electrode which receives a third initialization gate signal, a first electrode which receives the pre-charging voltage, and a second electrode connected to the third node.

In an embodiment, the third initialization transistor may be an NMOS transistor including an oxide semiconductor.

In an embodiment, the pixel driving circuit part and the light-emitting element may constitute a pixel which sequentially performs an anode initialization operation, a gate initialization operation, a data writing operation, a threshold voltage compensation operation, an anode holding operation, and a light-emitting operation, and the data writing operation and the threshold voltage compensation operation may be performed in a same operation period.

In an embodiment, in a first period where the anode initialization operation is performed, the first gate signal, the second gate signal, and the second initialization gate signal may have inactive levels, and the first initialization gate signal, the third initialization gate signal, and the emission control signal may have active levels. In a second period where the gate initialization operation is performed, the first gate signal, the second gate signal, and the emission control signal may have inactive levels, and the first initialization gate signal, the second initialization gate signal, and third initialization gate signal may have active levels. In a third period where the data writing operation and the threshold voltage compensation operation are performed, the second initialization gate signal, the third initialization gate signal, and the emission control signal may have inactive levels, and the first gate signal, the second gate signal, and the first initialization gate signal may have active levels.

In an embodiment, in a fourth period where the anode holding operation is performed, the first gate signal, the second gate signal, and the second initialization gate signal may have inactive levels, and the first initialization gate signal, the third initialization gate signal, and the emission control signal may have active levels. In a fifth period where the light-emitting operation is performed, the first gate signal, the second gate signal, the first initialization gate signal, and the second initialization gate signal may have inactive levels, and the third initialization gate signal and the emission control signal may have active levels.

In an embodiment, the first transistor, the third transistor, and the fourth transistor may be PMOS transistor formed in and on a silicon wafer substrate, and the second transistor may be an NMOS transistor including an oxide semiconductor.

In an embodiment, the second transistor may be configured to receive the date voltage or a reference voltage.

In an embodiment, the pixel driving circuit part and the light-emitting element may constitute a pixel which sequentially performs an anode initialization operation, a gate initialization operation, a data writing operation, a threshold voltage compensation operation, an anode holding operation, and a light-emitting operation, and the data writing operation and the threshold voltage compensation operation may be performed in a same operation period. In a first period where the anode initialization operation is performed, the second gate signal, and the second initialization gate signal may have inactive levels, and the first initialization gate signal, the first gate signal, and the emission control signal may have active levels. In a second period where the gate initialization operation is performed, the second gate signal, and the emission control signal may have inactive levels, and first gate signal, the first initialization gate signal and the second initialization gate signal may have active levels. In a third period where the data writing operation and the threshold voltage compensation operation are performed, the second initialization gate signal and the emission control signal may have inactive levels, and the first gate signal, the second gate signal, and the first initialization gate signal may have active levels.

In an embodiment, in a fourth period where the anode holding operation is performed, the second gate signal, and the second initialization gate signal may have inactive levels, and the first gate signal, the first initialization gate signal and the emission control signal may have active levels. In a fifth period where the light-emitting operation is performed, the second gate signal, the first initialization gate signal, and the second initialization gate signal may have inactive levels, and the first gate signal, and the emission control signal may have active levels.

In an embodiment, in the first period, the second period, the fourth period, and the fifth period, the third node may receive the reference voltage. In the third period, the third node may receive the date voltage.

An electronic device according to embodiments of the present disclosure includes a display device including: a display panel including: a circuit layer including a pixel driving circuit part and a light-emitting element disposed on the circuit layer and electrically connected to the pixel driving circuit part, a date driver which provides a data voltage to the display panel, a gate driver which provides gate signals to the display panel, an emission driver which provides an emission control signal to the display panel, and a controller which controls the data driver, the gate drive, and the emission driver based on an input image data and a control signal, and a processor which provides the input image data and the control signal to the controller. The pixel driving circuit part includes: a first transistor including a gate electrode connected to a first node, a first electrode which receives a first power voltage, and a second electrode connected to a second node, a second transistor including a gate electrode which receives a first gate signal, a first electrode which receives the date voltage, and a second electrode connected to a third node, a third transistor including a gate electrode which receives a second gate signal, a first electrode connected to the first node, and a second electrode connected to the second node, a fourth transistor including a gate electrode which receives the emission control signal, a first electrode connected to the second node, and a second electrode connected to a fourth node, a first initialization transistor, which is an NMOS transistor, includes a gate electrode which receives a first initialization gate signal, a first electrode which receives an initialization voltage, and a second electrode connected to the fourth node, a second initialization transistor, which is an NMOS transistor, includes a gate electrode which receives a second initialization gate signal, a first electrode which receives a pre-charging voltage, and a second electrode connected to the first node, and a capacitor connected between the third node and the first node. The light-emitting element includes an anode electrode connected to the fourth node and a cathode electrode which receives a second power voltage.

In an embodiment, the circuit layer may further include a first insulating layer disposed on a silicon wafer substrate and a second insulating layer disposed on the first insulating layer, the first transistor, the second transistor, the third transistor, and the fourth transistor may be formed in and on the silicon wafer substrate, and the first initialization transistor and the second initialization transistor may be disposed on the first insulating layer.

In an embodiment, the NMOS transistors of the first initialization transistor and the second initialization transistor may include oxide semiconductors.

In an embodiment, the first transistor, the second transistor, the third transistor, and the fourth transistor may be PMOS transistors.

In an embodiment, the pixel driving circuit part may further include a third initialization transistor including a gate electrode which receives a third initialization gate signal, a first electrode which receives the pre-charging voltage, and a second electrode connected to the third node, and the third initialization transistor may be an NMOS transistor including an oxide semiconductor.

According to embodiments of the present disclosure, a display panel of a display device may include a circuit layer including a pixel driving circuit part, and a light-emitting element disposed on the circuit layer. The pixel driving circuit part may include a first transistor which is a driving transistor, second and third transistors which operates in response to gate signals, a fourth transistor which operates in response to an emission control signal, first, second, and third initialization transistors which operates in response to initialization gate signals, and a capacitor. A first electrode of the second transistor may receive a data voltage, a first electrode of the first initialization transistor may receive an initialization voltage, and first electrodes of the second and third initialization transistors may receive a pre-charging voltage.

The first, third, and fourth transistors may be PMOS transistors formed on a silicon wafer substrate, and the first, second, and third initialization transistors may be NMOS transistors including an oxide semiconductor. The second transistor may be a PMOS transistor formed on the silicon wafer substrate or an NMOS transistor including an oxide semiconductor. Alternatively, the third initialization transistor may be omitted, and the first electrode of the second transistor may receive the data voltage or a reference voltage. Accordingly, the gate-source voltage of the fifth transistor may be stably maintained, thereby ensuring excellent contrast ratio. In addition, the leakage current flowing through the capacitor may be minimized.

In addition, the first, second, and third initialization transistors may be disposed on the first, second, third, and fourth transistors. Accordingly, the integration density of the pixels may be improved. In case the integration density of the pixels is effectively improved, the display device may display high-resolution images. In addition, the number of masks used in the manufacturing process of the display device may be effectively reduced.

### BRIEF DESCRIPTION OF THE DRAWINGS

Illustrative, non-limiting embodiments will be more clearly understood from the following detailed description in conjunction with the accompanying drawings.

FIG. 1 is a block diagram schematically illustrating a display device according to embodiments of the present disclosure.

FIG. 2 is a circuit diagram illustrating an example of a circuit structure of one pixel of FIG. 1.

FIG. 3 is a cross-sectional view schematically illustrating a display panel and an encapsulation substrate of FIG. 1.

FIG. 4 is an enlarged cross-sectional view of a portion of a transistor substrate of FIG. 3.

FIG. 5 is a waveform diagram for explaining an operation of the pixel of FIG. 2.

FIGS. 6, 7, 8, 9, and 10 are circuit diagrams for explaining each operation period of the pixel of FIG. 5.

FIG. 11 is a circuit diagram illustrating another example of the circuit structure of one pixel of FIG. 1.

FIG. 12 is a waveform diagram for explaining an operation of the pixel of FIG. 11.

FIG. 13 is a circuit diagram illustrating another example of the circuit structure of one pixel of FIG. 1.

FIG. 14 is a waveform diagram for explaining an operation of the pixel of FIG. 13.

FIG. 15 is a block diagram illustrating an electronic device according to embodiments of the present disclosure.

FIG. 16 is a schematic diagram illustrating an electronic device according to various embodiments.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element, it can be directly on the other element or intervening elements may be present therebetween. In contrast, when an element is referred to as being “directly on” another element, there are no intervening elements present.

Hereinafter, embodiments of the present disclosure will be explained in detail with reference to the accompanying drawings. The same reference numerals are used for the same components in the drawings, and redundant descriptions of the same components will be omitted.

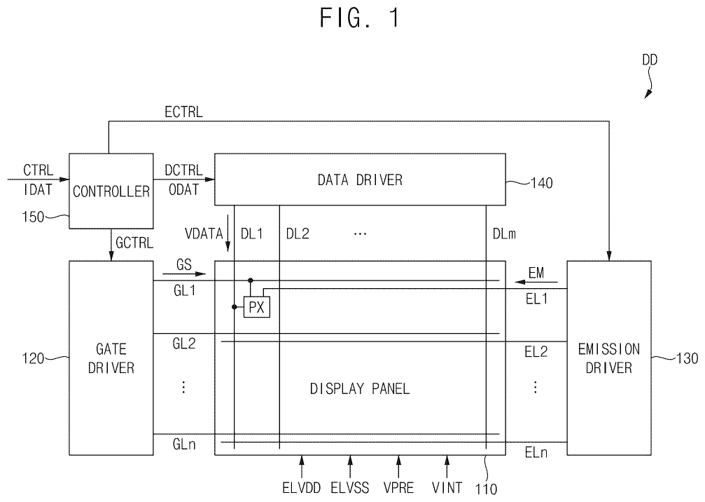

FIG. 1 is a block diagram schematically illustrating a display device according to embodiments of the present disclosure.

Referring to FIG. 1, a display device DD according to embodiments of the present disclosure may include a display panel 110, a gate driver 120, an emission driver 130, a data driver 140, and a controller 150.

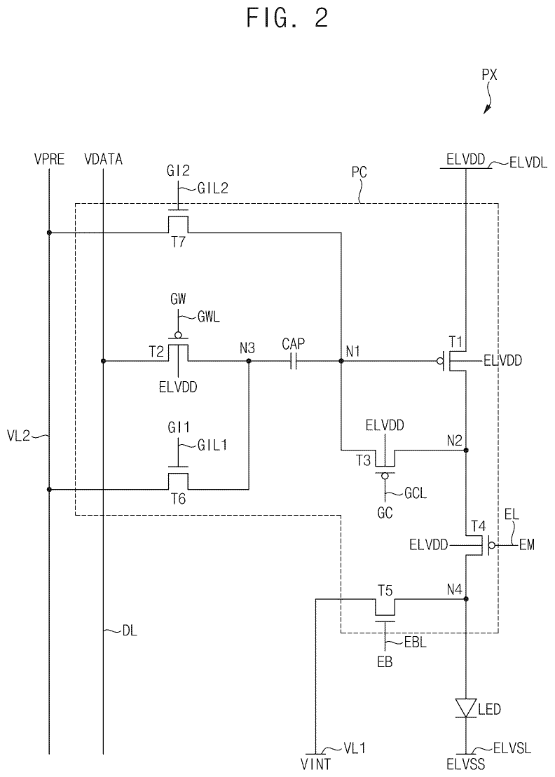

The display panel 110 may include a plurality of gate lines GL1 to GLn, a plurality of data lines DL1 to DLm, a plurality of emission control lines EL1 to ELn, and a plurality of pixels PX (where n and m are integers of 2 or more). The gate lines GL1 to GLn, the emission control lines EL1 to ELn, and the data lines DL1 to DLm may be electrically connected to the pixels PX. The gate lines GL1 to GLn may receive a gate signal GS, the emission control lines EL1 to ELn may receive an emission control signal EM, and the data lines DL1 to DLm may receive a data voltage VDATA. For example, the gate signal GS may include at least one of gate signals GW, GC, EB, GI1, and GI2 of FIG. 2.

Each of the gate lines GL1 to GLn may extend in a first direction (e.g., a row direction). Each of the emission control lines EL1 to ELn may extend in the first direction. Each of the data lines DL1 to DLm may extend in a second direction intersecting the first direction (e.g., a column direction). The gate lines GL1 to GLn, the emission control lines EL1 to ELn, and the data lines DL1 to DLm may be insulated from each other. The pixels PX may be arranged in areas where the gate lines GL1 to GLn (or the emission control lines EL1 to ELn) intersect the data lines DL1 to DLm.

In an embodiment, each of the pixels PX may include a switching transistor which supplies the data voltage VDATA in response to the gate signal GS, a storage capacitor which stores the data voltage VDATA supplied by the switching transistor, a driving transistor which generates a driving current based on the data voltage VDATA stored in the storage capacitor, and a light-emitting element which emits light based on the driving current generated by the driving transistor. For example, the light-emitting element may include a light emitting diode (LED), an organic light emitting diode (OLED), or a quantum dot (QD) light-emitting element.

The pixels PX may receive a first power voltage ELVDD and a second power voltage ELVSS. The pixels PX may receive the data voltage VDATA in response to the gate signal GS and the emission control signal EM, and generate light of a gray level corresponding to the data voltage VDATA using the first power voltage ELVDD and the second power voltage ELVSS. In addition, the pixels PX may further receive a pre-charging voltage VPRE and an initialization voltage VINT.

The gate driver 120 may provide the gate signals GS to the pixels PX through the gate lines GL1 to GLn based on a gate control signal GCTRL received from the controller 150. In an embodiment, the gate driver 120 may sequentially provide the gate signals GS to the pixels PX in units of rows. The gate control signal GCTRL may include a gate start signal, a gate clock signal, and the like, but the embodiments of the present disclosure are not necessarily limited thereto. For example, the gate driver 120 may be integrated in or formed at a peripheral portion of the display panel 110. Alternatively, the gate driver 120 may be implemented as one or more integrated circuits (ICs).

The emission driver 130 may provide the emission control signals EM to the pixels PX through the emission control lines EL1 to ELn based on an emission driving control signal ECTRL received from the controller 150. In an embodiment, the emission driver 130 may sequentially provide the emission control signals EM to the pixels PX in units of rows. The emission driving control signal ECTRL may include an emission start signal, an emission clock signal, and the like, but the embodiments of the present disclosure are not necessarily limited thereto. For example, the emission driver 130 may be integrated in or formed at a peripheral portion of the display panel 110. Alternatively, the emission driver 130 may be implemented as one or more integrated circuits (ICs).

The data driver 140 may receive a data control signal DCTRL and an output image data ODAT from the controller 150, and may provide the data voltages VDATA to the pixels PX through the data lines DL1 to DLm based on the data control signal DCTRL and the output image data ODAT. The data control signal DCTRL may include an output data enable signal, a horizontal start signal, a load signal, and the like, but the embodiments of the present disclosure are not necessarily limited thereto. For example, the data driver 140 may be implemented as a single integrated circuit, and the integrated circuit may be referred to as a timing controller embedded data driver (TED). Alternatively, the data driver 140 may be implemented as separate integrated circuits.

The controller 150 may receive an input image data IDAT and a control signal CTRL from an external host processor. For example, the controller 150 may be a timing controller, and the host processor may be an application processor (AP), a graphic processing unit (GPU), or a graphic card. In an embodiment, the input image data IDAT may be RGB image data including red, green, and blue image data. The control signals CTRL may include a vertical sync signal, a horizontal sync signal, an input data enable signal, a master clock signal, and the like, but the embodiments of the present disclosure are not necessarily limited thereto.

The controller 150 may generate the gate control signal GCTRL, the emission driving control signal ECTRL, the data control signal DCTRL, and the output image data ODAT based on the input image data IDAT and the control signal CTRL. The controller 150 may provide the gate control signal GCTRL to the gate driver 120 to control the operation of the gate driver 120. The controller 150 may provide the emission driving control signal ECTRL to the emission driver 130 to control the operation of the emission driver 130. In addition, the controller 150 may provide the output image data ODAT and the data control signal DCTRL to the data driver 140 to control the operation of the data driver 140.

FIG. 2 is a circuit diagram illustrating an example of a circuit structure of one pixel of FIG. 1.

Referring to FIG. 2, one pixel PX may include a pixel driving circuit part PC and a light-emitting element LED electrically connected to the pixel driving circuit part PC. The pixel driving circuit part PC may generate a driving current, and the light-emitting element LED may generate light based on the driving current.

In an embodiment, the pixel driving circuit part PC may include a first transistor T1, a second transistor T2, a third transistor T3, a fourth transistor T4, a fifth transistor T5, a sixth transistor T6, a seventh transistor T7, and a capacitor CAP.

In an embodiment, the first transistor T1, the second transistor T2, the third transistor T3, and the fourth transistor T4 may be PMOS transistors, and the fifth transistor T5, the sixth transistor T6, and the seventh transistor T7 may be NMOS transistors.

In an embodiment, the first transistor T1, the second transistor T2, the third transistor T3, and the fourth transistor T4 may be metal-oxide-semiconductor field-effect transistors (MOSFETs) formed through a semiconductor process. That is, the first transistor T1, the second transistor T2, the third transistor T3, and the fourth transistor T4 may be formed in and on a silicon wafer substrate.

In an embodiment, the fifth transistor T5, the sixth transistor T6, and the seventh transistor T7 may be formed using an oxide semiconductor.

In case the fifth transistor T5 is an NMOS transistor formed using an oxide semiconductor, a gate-source voltage of the fifth transistor T5 may be stably maintained. In this case, an excellent contrast ratio may be achieved. In addition, in case the sixth transistor T6, and the seventh transistor T7 are NMOS transistors formed using oxide semiconductors, leakage current flowing through the capacitor CAP may be minimized.

The first transistor T1 may include a gate electrode, a first electrode, and a second electrode. The gate electrode of the first transistor T1 may be connected to a first node N1. The first electrode of the first transistor T1 may be connected to a first power line ELVDL which receives the first power voltage ELVDD. The second electrode of the first transistor T1 may be connected to a second node N2. The first transistor T1 may provide the driving current to the light-emitting element LED. The first transistor T1 may be referred to as a “driving transistor”.

The first transistor T1 may further include a body electrode. The body electrode of the first transistor T1 may receive the first power voltage ELVDD. For example, the body electrode of the first transistor T1 may be connected to the first power line ELVDL. Alternatively, a power voltage different from the first power voltage ELVDD may be applied to the body electrode of the first transistor T1.

The second transistor T2 may include a gate electrode, a first electrode, and a second electrode. The gate electrode of the second transistor T2 may be connected to a first gate line GWL which receives the first gate signal GW. The first electrode of the second transistor T2 may be connected to a data line DL which receives the data voltage VDATA. The second electrode of the second transistor T2 may be connected to a third node N3.

The second transistor T2 may further include a body electrode. The body electrode of the second transistor T2 may receive the first power voltage ELVDD. For example, the body electrode of the second transistor T2 may be connected to the first power line ELVDL. Alternatively, a power voltage different from the first power voltage ELVDD may be applied to the body electrode of the second transistor T2.

The second transistor T2 may be turned on or off in response to the first gate signal GW. For example, in case the first gate signal GW has an active level, the second transistor T2 may be turned on. In this case, the second transistor T2 may provide the data voltage VDATA to the third node N3. Conversely, in case the first gate signal GW has an inactive level, the second transistor T2 may be turned off. In this case, the second transistor T2 may block the supply of the data voltage VDATA.

The third transistor T3 may include a gate electrode, a first electrode, and a second electrode. The gate electrode of the third transistor T3 may be connected to a second gate line GCL which receives the second gate signal GC. The first electrode of the third transistor T3 may be connected to the first node N1. The second electrode of the third transistor T3 may be connected to the second node N2.

The third transistor T3 may further include a body electrode. The body electrode of the third transistor T3 may receive the first power voltage ELVDD. For example, the body electrode of the third transistor T3 may be connected to the first power line ELVDL which receives the first supply voltage ELVDD. Alternatively, a power voltage different from the first power voltage ELVDD may be applied to the body electrode of the third transistor T3.

The third transistor T3 may be turned on or turned off in response to the second gate signal GC. For example, in case the second gate signal GC has an active level, the third transistor T3 may be turned on. In this case, the third transistor T3 may diode-connect the first transistor T1. That is, the third transistor T3 may compensate for a threshold voltage of the first transistor T1. Conversely, in case the second gate signal GC has an inactive level, the third transistor T3 may be turned off. In this case, the first transistor T1 may not be diode-connected.

The fourth transistor T4 may include a gate electrode, a first electrode, and a second electrode. The gate electrode of the fourth transistor T4 may be connected to an emission control line EL which receives the emission control signal EM. The first electrode of the fourth transistor T4 may be connected to the second node N2. The second electrode of the fourth transistor T4 may be connected to a fourth node N4.

The fourth transistor T4 may further include a body electrode. The body electrode of the fourth transistor T4 may receive the first power voltage ELVDD. For example, the body electrode of the fourth transistor T4 may be connected to the first power line ELVDL which receives the first supply voltage ELVDD. Alternatively, a power voltage different from the first power voltage ELVDD may be applied to the body electrode of the fourth transistor T4.

The fourth transistor T4 may be turned on or turned off in response to the emission control signal EM. For example, in case the emission control signal EM has an active level, the fourth transistor T4 may be turned on. In this case, the fourth transistor T4 may provide the driving current generated by the first transistor T1 to the fourth node N4. Conversely, in case the emission control signal EM has an inactive level, the fourth transistor T4 may be turned off. In this case, the fourth transistor T4 may block the supply of the driving current generated by the first transistor T1.

The fifth transistor T5 may include a gate electrode, a first electrode, and a second electrode. The gate electrode of the fifth transistor T5 may be connected to a third gate line EBL which receives the third gate signal EB. The first electrode of the fifth transistor T5 may be connected to a first voltage line VL1 which receives the initialization voltage VINT. The second electrode of the fifth transistor T5 may be connected to the fourth node N4.

The fifth transistor T5 may be turned on or turned off in response to the third gate signal EB. For example, in case the third gate signal EB has an active level, the fifth transistor T5 may be turned on. In this case, the fifth transistor T5 may provide the initialization voltage VINT to the fourth node N4. Conversely, in case the third gate signal EB has an inactive level, the fifth transistor T5 may be turned off. In this case, the fifth transistor T5 may block the supply of the initialization voltage VINT.

The sixth transistor T6 may include a gate electrode, a first electrode, and a second electrode. The gate electrode of the sixth transistor T6 may be connected to a fourth gate line GIL1 which receives the fourth gate signal GI1. The first electrode of the sixth transistor T6 may be connected to the first voltage line VL1 which receives the pre-charging voltage VPRE. The second electrode of the sixth transistor T6 may be connected to the third node N3.

The sixth transistor T6 may be turned on or turned off in response to the fourth gate signal GI1. For example, in case the fourth gate signal GI1 has an active level, the sixth transistor T6 may be turned on. In this case, the sixth transistor T6 may provide the pre-charging voltage VPRE to the third node N3. Conversely, in case the fourth gate signal GI1 has an inactive level, the sixth transistor T6 may be turned off. In this case, the sixth transistor T6 may block the supply of the pre-charging voltage VPRE.

The seventh transistor T7 may include a gate electrode, a first electrode, and a second electrode. The gate electrode of the seventh transistor T7 may be connected to a fifth gate line GIL2 which receives the fifth gate signal GI2. The first electrode of the seventh transistor T7 may be connected to the first voltage line VL1 which receives the pre-charging voltage VPRE. The second electrode of the seventh transistor T7 may be connected to the first node N1.

The seventh transistor T7 may be turned on or turned off in response to the fifth gate signal GI2. For example, in case the fifth gate signal GI2 has an active level, the seventh transistor T7 may be turned on. In this case, the seventh transistor T7 may supply the pre-charging voltage VPRE to the first node N1. Conversely, in case the fifth gate signal GI2 has an inactive level, the seventh transistor T7 may be turned off. In this case, the seventh transistor T7 may block the supply of the pre-charging voltage VPRE.

In this specification, the third gate signal EB may be referred to as a “first initialization gate signal”, the fifth gate signal GI2 may be referred to as a “second initialization gate signal”, and the fourth gate signal GI1 may be referred to as a “third initialization gate signal”. In addition, the fifth transistor T5 may be referred to as a “first initialization transistor”, the seventh transistor T7 may be referred to as a “second initialization transistor”, and the sixth transistor T6 may be referred to as a “third initialization transistor”.

The capacitor CAP may include a first electrode and a second electrode. The first electrode of the capacitor CAP may be connected to the third node N3. The second electrode of the capacitor CAP may be connected to the first node N1. The capacitor CAP may store a differential voltage between a gate voltage and a source voltage of the first transistor T1.

The light-emitting element LED may include an anode electrode and a cathode electrode. The anode electrode of the light-emitting element LED may be connected to the fourth node N4. The cathode electrode of the light-emitting element LED may be connected to a second power line ELVSL which receives a second power voltage ELVSS. The second power voltage ELVSS may have a voltage level lower than the first power voltage ELVDD.

Although FIG. 2 illustrates that one pixel driving circuit part PC includes seven transistors and one capacitor, the embodiments of the present disclosure are not necessarily limited thereto.

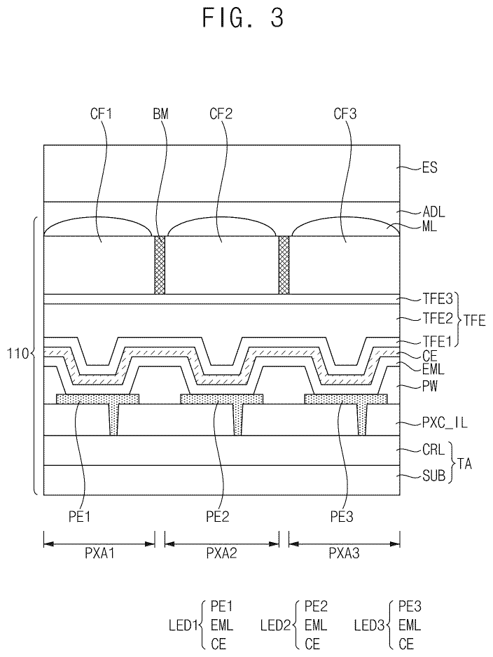

FIG. 3 is a cross-sectional view schematically illustrating a display panel and an encapsulation substrate of FIG. 1.

Referring to FIG. 3, the display device DD according to embodiments of the present disclosure may further include an encapsulation substrate ES disposed on the display panel DP. The display panel 110 may include a transistor substrate TA, a circuit insulating layer PXC_IL, first, second, and third light-emitting elements LED1, LED2, and LED3, a partition wall PW, an encapsulation layer TFE, first, second, and third color filter layers CF1, CF2, and CF3, a light-blocking layer BM, and a lens layer. The transistor substrate TA may include a substrate SUB and a circuit layer CRL.

Here, the first light-emitting element LED1 may include a first pixel electrode PE1, a light-emitting layer EML, and a common electrode CE; the second light-emitting element LED2 may include a second pixel electrode PE2, the light-emitting layer EML, and the common electrode CE, and the third light-emitting element LED3 may include a third pixel electrode PE3, the light-emitting layer EML, and the common electrode CE. The first light-emitting element LED1 may be disposed in a first pixel area PXA1, the second light-emitting element LED2 may be disposed in a second pixel area PXA2, and the third light-emitting element LED3 may be disposed in a third pixel area PXA3.

In an embodiment, the substrate SUB may include a silicon wafer substrate formed using a semiconductor process. The substrate SUB may be a support member for supporting other components of the display device DD. For example, the substrate SUB may include a semiconductor material (e.g., group IV semiconductor, group III-V compound semiconductor, group II-VI semiconductor, and the like). However, the embodiments of the present disclosure are not necessarily limited thereto. In this specification, the substrate SUB may be referred to as a “silicon wafer substrate”.

The circuit layer CRL may be disposed on the substrate SUB. The circuit layer CRL may include various driving elements, circuit lines, insulating layers, gate lines, data lines, and emission control lines for driving the first, second, and third light-emitting elements LED1, LED2, and LED3. For example, the circuit layer CRL may include the pixel driving circuit part PC of FIG. 2. That is, the circuit layer CRL may include the first, second, third, fourth, fifth, sixth, and seventh transistors T1, T2, T3, T4, T5, T6, and T7 and the capacitor CAP of FIG. 2.

The circuit insulating layer PXC_IL may be disposed on the circuit layer CRL. The circuit insulating layer PXC_IL may prevent contact between the first, second, and third pixel electrodes PE1, PE2, and PE3 and the circuit layer CRL. The circuit insulating layer PXC_IL may include an organic material and/or an inorganic material. For example, the circuit insulating layer PXC_IL may include a plurality of layers formed of various insulating materials.

The first, second, and third pixel electrodes PE1, PE2, and PE3 may be disposed on the circuit insulating layer PXC_IL. The first pixel electrode PE1 may overlap the first pixel area PXA1, the second pixel electrode PE2 may overlap the second pixel area PXA2, and the third pixel electrode PE3 may overlap the third pixel area PXA3.

The first pixel electrode PE1 may be electrically connected to a transistor of the circuit layer CRL through a contact hole penetrating the circuit insulating layer PXC_IL in the first pixel area PXA1, the second pixel electrode PE2 may be electrically connected to a transistor of the circuit layer CRL through a contact hole in the second pixel area PXA2, and the third pixel electrode PE3 may be electrically connected to a transistor of the circuit layer CRL through a contact hole in the third pixel area PXA3.

The first, second, and third pixel electrodes PE1, PE2, and PE3 may include a metal, an alloy, a metal nitride, a conductive metal oxide, a transparent conductive material, and the like. The first, second, and third pixel electrodes PE1, PE2, and PE3 may include the same material and be formed through the same process. For example, the first, second, and third pixel electrodes PE1, PE2, and PE3 may have a multilayer structure including ITO/Ag/ITO. However, the embodiments of the present disclosure are not necessarily limited thereto. The first, second, and third pixel electrodes PE1, PE2, and PE3 may be anode electrodes. The first, second, and third pixel electrodes PE1, PE2, and PE3 may be reflective electrodes. However, the embodiments of the present disclosure are not necessarily limited thereto.

The partition wall PW may be disposed on the circuit insulating layer PXC_IL. The partition wall PW may cover edges of the first, second, and third pixel electrodes PE1, PE2, and PE3. In addition, the partition wall PW may expose at least portion of upper surfaces of the first, second, and third pixel electrodes PE1, PE2, and PE3. For example, the partition wall PW may include an inorganic material such as silicon oxide, silicon nitride, or silicon oxynitride. These may be used alone or in combination with each other. Alternatively, the partition wall PW may include an organic material. In an embodiment, the partition wall PW may have a multilayer structure, but the embodiments of the present disclosure are not necessarily limited thereto.

The light-emitting layer EML may be disposed on the first, second, and third pixel electrodes PE1, PE2, and PE3 and the partition wall PW. The light-emitting layer EML may be a common layer formed over the first, second, and third pixel areas PXA1, PXA2, and PXA3. That is, the light-emitting layer EML may continuously extend over an entirety of the first, second, and third pixel areas PXA1, PXA2, and PXA3. For example, the light-emitting layer EML may include a hole injection layer, a hole transport layer, an organic light-emitting layer, an electron injection layer, and an electron transport layer. In an embodiment, the organic light-emitting layer may include a light-emitting material which emits white light. For example, the white light may be a mixture of blue light, green light, and red light. Alternatively, the white light may be a mixture of blue light and yellow light.

However, the embodiments of the present disclosure are not necessarily limited thereto. The light-emitting layer EML may include a first light-emitting layer patterned to overlap the first pixel area PXA1 and including a light-emitting material which emits red light, a second light-emitting layer patterned to overlap the second pixel area PXA2 and including a light-emitting material which emits green light, and a third light-emitting layer patterned to overlap the third pixel area PXA3 and including a light-emitting material that emits blue light. In this case, the first, second, and third light-emitting layers may be separated from each other, and the first, second, and third color filter layers CF1, CF2, and CF3 and the light-blocking layer BM may be omitted.

The common electrode CE may be disposed on the light-emitting layer EML. The common electrode CE may be a common layer formed over the first, second, and third pixel areas PXA1, PXA2, and PXA3. That is, the common electrode CE may continuously extend over the entirety of the first, second, and third pixel areas PXA1, PXA2, and PXA3. For example, the common electrode CE may include a metal, an alloy, a metal nitride, a conductive metal oxide, a transparent conductive material, and the like. These may be used alone or in combination with each other. The common electrode CE may be a cathode electrode. The common electrode CE may be a transmissive or semi-transmissive electrode.

Accordingly, in the first pixel area PXA1, the first pixel electrode PE1, the light-emitting layer EML, and the common electrode CE may form the first light-emitting element LED1. In the second pixel area PXA2, the second pixel electrode PE2, the light-emitting layer EML, and the common electrode CE may form the second light-emitting element LED2. In the third pixel area PXA3, the third pixel electrode PE3, the light-emitting layer EML, and the common electrode CE may form the third light-emitting element LED3.

The encapsulation layer TFE may be disposed on the common electrode CE. The encapsulation layer TFE may continuously extend over the entirety of the first, second and third pixel areas PXA1, PXA2, and PXA3. The encapsulation layer TFE may prevent impurities, moisture, or the like from penetrating into the first, second and third light-emitting elements LED1, LED2, and LED3 from the outside.

The encapsulation layer TFE may include at least one inorganic layer and at least one organic layer. For example, the encapsulation layer TFE may include a first inorganic encapsulation layer TFE1, an organic encapsulation layer TFE2 disposed on the first inorganic encapsulation layer TFE1, and a second inorganic encapsulation layer TFE3 disposed on the organic encapsulation layer TFE2. The organic encapsulation layer TFE2 may have a substantially planar upper surface.

For example, the first and third inorganic encapsulation layers TFE1 and TFE3 may include silicon oxide, silicon nitride, silicon oxynitride, and the like. These may be used alone or in combination with each other. The organic encapsulation layer TFE2 may include a polymer cured material such as polyacrylate.

The first, second, and third color filter layers CF1, CF2, and CF3 may be disposed on the encapsulation layer TFE. The first color filter layer CF1 may overlap the first pixel area PXA1, the second color filter layer CF2 may overlap the second pixel area PXA2, and the third color filter layer CF3 may overlap the third pixel area PXA3. The first, second, and third color filter layers CF1, CF2, and CF3 may selectively transmit light of specific wavelengths and absorb light of the remaining wavelengths. For example, red light may be transmitted through the first color filter layer CF1, green light may be transmitted through the second color filter layer CF2, and blue light may be transmitted through the third color filter layer CF3. Accordingly, the first pixel area PXA1 may emit red light, the second pixel area PXA2 may emit green light, and the third pixel area PXA3 may emit blue light. However, the embodiments of the present disclosure are not necessarily limited thereto.

The light-blocking layer BM may be disposed on the encapsulation layer TFE. The light-blocking layer BM may be disposed between the first, second, and third color filter layers CF1, CF2, and CF3. That is, the light-blocking layer BM may not overlap the first, second, and third pixel areas PXA1, PXA2, and PXA3. The light-blocking layer BM may block light incident on the light-blocking layer BM. Accordingly, the light-blocking layer BM may prevent color mixing between the first, second, and third pixel areas PXA1, PXA2, and PXA3. For example, the light-blocking layer BM may include an organic and/or inorganic material containing black pigment, black dye, and the like.

The lens layer may be disposed on the first, second, and third color filter layers CF1, CF2, and CF3 and the light-blocking layer BM. The lens layer may include a plurality of micro lenses ML. The micro lenses ML may improve light extraction efficiency. Each of the micro lenses ML may overlap the first, second, and third pixel areas PXA1, PXA2, and PXA3. The micro lenses ML may have a predetermined refractive index with respect to visible light. For example, the micro lenses ML may have a refractive index of about 1.5 to about 1.7 with respect to visible light. However, the embodiments of the present disclosure are not necessarily limited thereto. For example, each of the micro lenses ML may have a convex cross-sectional shape.

The encapsulation substrate ES may be disposed on the lens layer. The encapsulation substrate ES may be attached to the display panel 110 through an adhesive layer ADL. The encapsulation substrate ES may protect the display panel 110 from moisture or gas ingress. The encapsulation substrate ES may include a transparent insulating substrate. For example, the encapsulation substrate ES may include glass. The adhesive layer ADL may include an optical clear adhesive (OCA), a pressure sensitive adhesive (PSA), a photo-curable resin, a thermosetting resin, or the like.

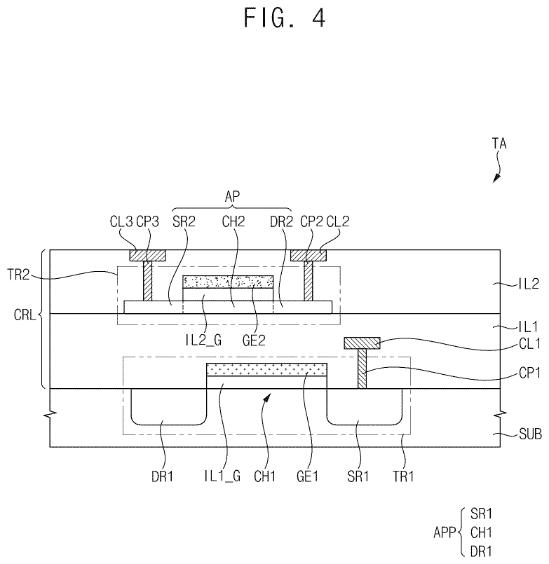

FIG. 4 is an enlarged cross-sectional view of a portion of a transistor substrate of FIG. 3.

Referring to FIG. 4, as described above, the transistor substrate TA may include the substrate SUB and the circuit layer CRL disposed on the substrate SUB. Here, the circuit layer CRL may include a first transistor TR1, a first contact part CP1, a first circuit line CL1, a first insulating layer IL1, a second transistor TR2, a second insulating layer IL2, a second contact part CP2, a second circuit line CL2, a third contact part CP3, and a third circuit line CL3.

In an embodiment, the first transistor TR1 may be a transistor (i.e., a metal-oxide-semiconductor field-effect transistor (MOSFET)) formed through a semiconductor process. The first transistor TR1 may include an active portion APP, a first gate insulating layer IL1_G, and a first gate electrode GE1. Here, a portion of the substrate SUB may define the active portion APP. The active portion APP may include a first source region SR1, a first drain region DR1, and a first channel region CH1.

In an embodiment, the first transistor TR1 may correspond to the first transistor T1, the second transistor T2, the third transistor T3, and the fourth transistor T4 of FIG. 2.

The substrate SUB may include a semiconductor material. In an embodiment, the substrate SUB may be a p-type semiconductor substrate doped with a p-type impurity or an n-type semiconductor substrate doped with an n-type impurity.

The first source region SR1 and the first drain region DR1 may be disposed inside the substrate SUB. Specifically, the first source region SR1 may be disposed at one side of the substrate SUB, and the first drain region DR1 may be disposed at the other side of the substrate SUB. For example, the first source region SR1 and the first drain region DR1 may include the same semiconductor material as the substrate SUB.

The first source region SR1 and the first drain region DR1 may be doped with impurities. Accordingly, the first source region SR1 and the first drain region DR1 may be conductive regions. The doping concentrations of the first source region SR1 and the first drain region DR1 may be higher than the doping concentration of the substrate SUB. In an embodiment, the first source region SR1 and the first drain region DR1 may be doped with a p-type impurity. That is, the first transistor TR1 may be a PMOS transistor.

At least a portion of the substrate SUB in contact with the first source region SR1 and the first drain region DR1 may be doped with an impurity of opposite type to an impurity of the first source region SR1 and the first drain region DR1. In an embodiment, in case the first source region SR1 and the first drain region DR1 are doped with a p-type impurity, the portion of the substrate SUB in contact with the first source region SR1 and the first drain region DR1 may be doped with an n-type impurity.

The first source region SR1 may correspond to a first electrode or a second electrode of the first transistor TR1, and the first drain region DR1 may correspond to a second electrode or a first electrode of the first transistor TR1.

The first channel region CH1 may be disposed between the first source region SR1 and the first drain region DR1 inside the substrate SUB. For example, the first channel region CH1 may include the same semiconductor material as the substrate SUB. The first channel region CH1 may be a region of the substrate SUB in which a carrier having a charge conducts when a voltage is applied to the gate electrode GE.

The first channel region CH1 may be defined as a current path formed between the first source region SR1 and the first drain region DR1. For example, in case the first source region SR1 and the first drain region DR1 are doped with a p-type impurity, the first channel region CH1 may be formed when a negative voltage is applied to the gate electrode GE and may transmit current through movement of holes.

The first gate insulating layer IL1_G may be disposed on the substrate SUB. Specifically, the first gate insulating layer IL1_G may overlap the first channel region CH1 in the plan view. The first gate insulating layer IL1_G may include silicon oxide (e.g., SiO₂), silicon nitride (SiNₓ), or an insulating material having a high-dielectric constant. The insulating material having the high-dielectric constant may refer to a dielectric material having a higher dielectric constant than the silicon oxide. For example, the insulating material having the high-dielectric constant may include aluminum oxide (Al₂O₃), tantalum oxide (Ta₂O₅), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃), and the like. These may be used alone or in combination with each other. The first gate insulating layer IL1_G may have a single-layer or a multi-layer in which a plurality of layers are stacked.

The first gate electrode GE1 may be disposed on the first gate insulating layer IL1_G. The first gate electrode GE1 may overlap the channel region CH1 in the plan view. The first gate electrode GE1 may include a semiconductor material such as doped polysilicon. Alternatively, the first gate electrode GE1 may include a metal or a metal nitride. Examples of metal may include aluminum, tungsten, copper, molybdenum, and the like. Examples of metal nitride may include titanium nitride (TiN), tantalum nitride (TaN), tungsten nitride (WN), and the like. These may be used alone or in combination with each other. However, the embodiments of the present disclosure are not necessarily limited thereto. The first gate electrode GE1 may have a single-layer or a multi-layer in which a plurality of layers are stacked.

The first insulating layer IL1 may be disposed on the substrate SUB and the first gate electrode GE1. The first insulating layer IL1 may cover the first gate electrode GE1. For example, the first insulating layer IL1 may include silicon oxide (SiOₓ), silicon nitride (SiNₓ), or an insulating material having a high-dielectric constant. These may be used alone or in combination with each other. The first insulating layer IL1 may have a single-layer or a multi-layer in which a plurality of layers are stacked.

The first contact part CP1 may be disposed inside the first insulating layer IL1. The first contact part CP1 may be electrically connected to the first source region SR1 (or the first drain region DR1).

The first circuit line CL1 may be disposed inside the first insulating layer IL1. The first circuit line CL1 may be disposed on the first contact part CP1 and may be electrically connected to the first contact part CP1. The first circuit line CL1 may receive various signals and/or voltages.

For example, the first contact part CP1 and the first circuit line CL1 may include a metal, a metal nitride, and the like. Example of the metal may include aluminum, tungsten, copper, molybdenum, and the like. Examples of the metal nitride may include titanium nitride (TiN), tantalum nitride (TaN), tungsten nitride (WN), and the like. These may be used alone or in combination with each other. However, the embodiments of the present disclosure are not necessarily limited thereto.

The second transistor TR2 may be disposed on the first insulating layer IL1. The second transistor TR2 may include an active pattern AP, a second gate insulating layer IL2_G, and a second gate electrode GE2. In an embodiment, the second transistor TR2 may correspond to the fifth transistor T5, the sixth transistor T6, and the seventh transistor T7 of FIG. 2.

The active pattern AP may be disposed on the first insulating layer IL1. In an embodiment, the active pattern AP may include an oxide semiconductor. For example, the oxide semiconductor may include zinc oxide (e.g., ZnO or ZnO₂), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), and the like, containing indium (In), zinc (Zn), gallium (Ga), tin (Sn), titanium (Ti), aluminum (Al), hafnium (Hf), zirconium (Zr), magnesium (Mg), and the like. These may be used alone or in combination with each other. However, the embodiments of the present disclosure are not necessarily limited thereto.

The active pattern AP may include a second channel region CH2, a second source region SR2, and a second drain region DR2. The second channel region CH2 may be located between the second source region SR2 and the second drain region DR2. The second source region SR2 and the second drain region DR2 may have higher conductivity than the second channel region CH2. For example, the second source region SR2 and the second drain region DR2 may be conductive regions as an n+ type. That is, the second transistor TR2 may be an NMOS transistor.

The second source region SR2 may correspond to a first electrode or a second electrode of the second transistor TR2, and the second drain region DR2 may correspond to a second electrode or a first electrode of the second transistor TR2.

The second gate insulating layer IL2_G may be disposed on the active pattern AP. Specifically, the second gate insulating layer IL2_G may overlap the second channel region CH2 in the plan view. For example, the second gate insulating layer IL2_G may include silicon oxide (SiOₓ), silicon nitride (SiNₓ), or an insulating material having a high-dielectric constant. These may be used alone or in combination with each other. The second gate insulating layer IL2_G may have a single-layer or a multi-layer in which a plurality of layers are stacked.

The second gate electrode GE2 may be disposed on the second gate insulating layer IL2_G. The second gate electrode GE2 may overlap the second channel region CH2 in the plan view. For example, the second gate electrode GE2 may include a metal, a metal nitride, and the like. Examples of the metal may include aluminum, tungsten, copper, molybdenum, and the like. Examples of the metal nitride may include titanium nitride (TiN), tantalum nitride (TaN), tungsten nitride (WN), and the like. These may be used alone or in combination with each other. However, the embodiments of the present disclosure are not necessarily limited thereto.

The second insulating layer IL2 may be disposed on the active pattern AP and the second gate electrode GE2. The second insulating layer IL2 may cover the active pattern AP and the second gate electrode GE2. For example, the second insulating layer IL2 may include silicon oxide (SiOₓ), silicon nitride (SiNₓ), or an insulating material having a high-dielectric constant. These may be used alone or in combination with each other. The second insulating layer IL2 may have a single-layer or a multi-layer in which a plurality of layers are stacked.

The second contact part CP2 may be disposed inside the second insulating layer IL2. The second contact part CP2 may be electrically connected to the second drain region DR2. In addition, the third contact part CP3 may be disposed inside the second insulating layer IL2. The third contact part CP3 may be electrically connected to the second source region SR2.

The second circuit line CL2 may be disposed inside the second insulating layer IL2. The second circuit line CL2 may be disposed on the second contact part CP2 and may be electrically connected to the second contact part CP2. The second circuit line CL2 may be electrically connected to any one of the first, second, and third pixel electrodes PE1, PE2, and PE3 of FIG. 2. Alternatively, the second circuit line CL2 may be electrically connected to a conductive pattern disposed in the first insulating layer IL1 and/or the second insulating layer IL2.

The third circuit line CL3 may be disposed inside the second insulating layer IL2. The third circuit line CL3 may be disposed on the third contact part CP3 and may be electrically connected to the third contact part CP3. The third circuit line CL3 may receive various voltages (e.g., a data voltage, a pre-charging voltage, or an initialization voltage).

For example, the second contact part CP2, the third contact part CP3, the second circuit line CL2, and the third circuit line CL3 may include a metal, a metal nitride, and the like. Examples of the metal may include aluminum, tungsten, copper, molybdenum, and the like. Examples of the metal nitride may include titanium nitride (TiN), tantalum nitride (TaN), tungsten nitride (WN), and the like. These may be used alone or in combination with each other. However, the embodiments of the present disclosure are not necessarily limited thereto.

As a result, in an embodiment, the second transistor TR2 formed of an oxide semiconductor may be disposed on the first transistor TR1 formed in and on a silicon wafer substrate (i.e., the substrate SUB). That is, the first, second, third, and fourth transistors T1, T2, T3, and T4 of FIG. 2 may be formed in and on the silicon wafer substrate, and the fifth, sixth, and seventh transistors T5, T6, and T7 may be disposed on the first, second, third, and fourth transistors T1, T2, T3, and T4. Accordingly, the integration density of the pixels (e.g., the pixels PX of FIG. 1) may be improved. In case the integration density of the pixels is improved, the display device DD may display high-resolution images. In addition, by disposing the second transistor TR2 on the first transistor TR1, the number of masks used in the manufacturing process of the display device DD may be reduced.

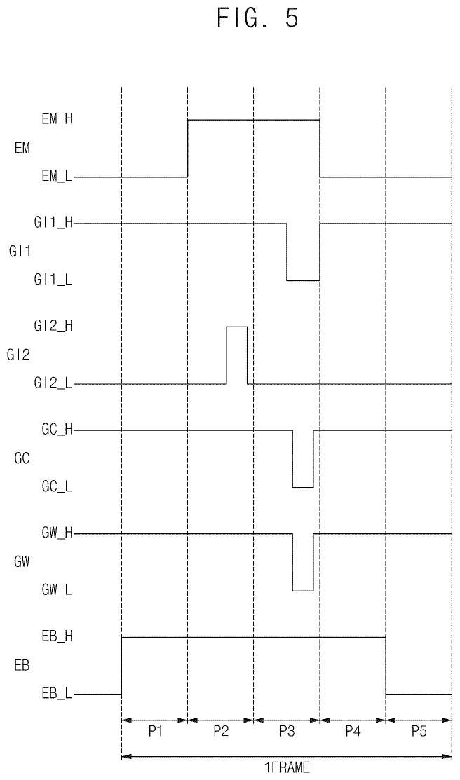

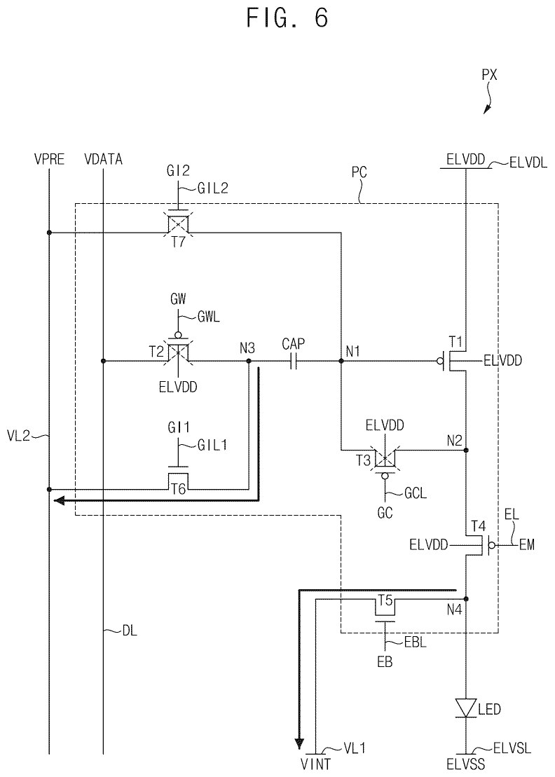

FIG. 5 is a waveform diagram for explaining an operation of the pixel of FIG. 2. FIGS. 6, 7, 8, 9, and 10 are circuit diagrams for explaining each operation period of the pixel of FIG. 5.

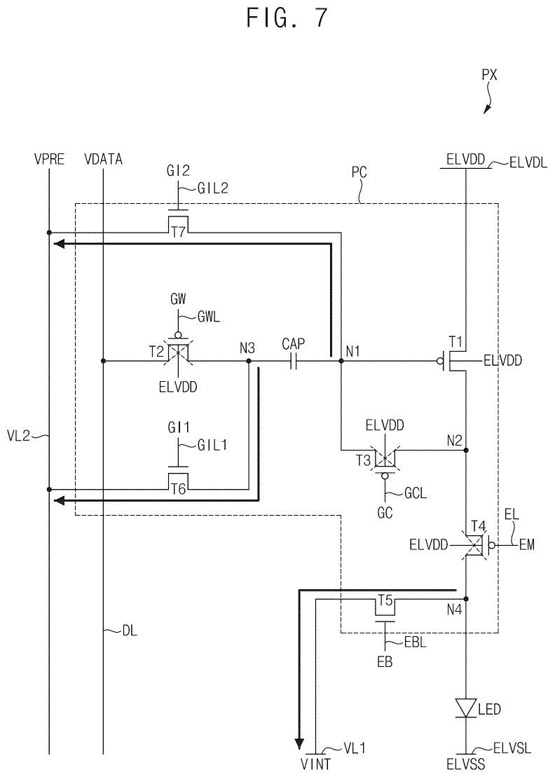

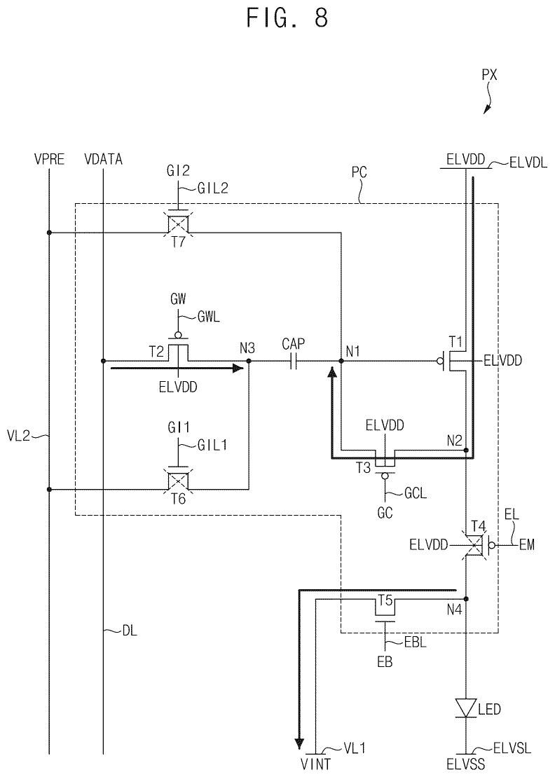

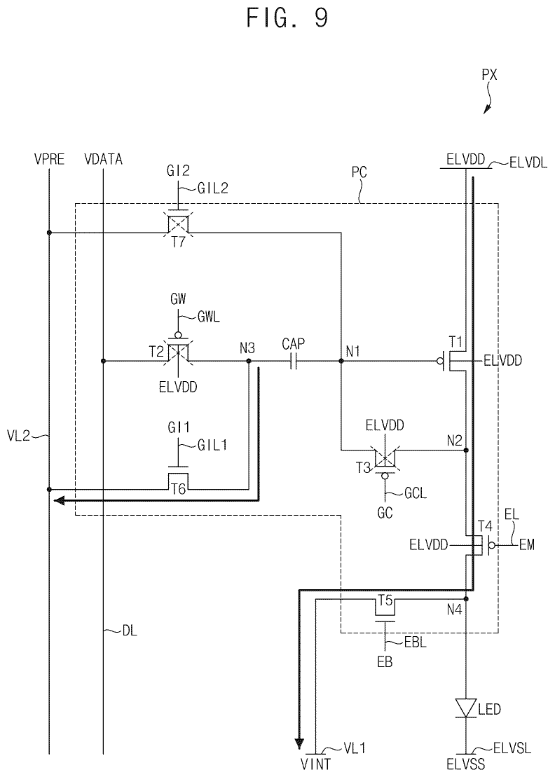

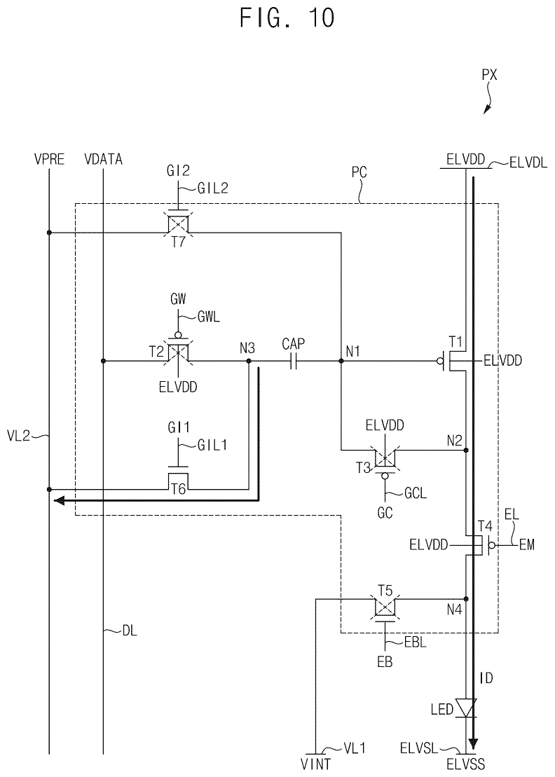

For example, FIG. 6 is a circuit diagram for explaining that an anode initialization operation performed by the pixel PX in a first period P1 of FIG. 5. FIG. 7 is a circuit diagram for explaining a gate initialization operation performed by the pixel PX in a second period P2 of FIG. 5. FIG. 8 is a circuit diagram for explaining a data writing operation and a threshold voltage compensation operation performed by the pixel PX in a third period P3 of FIG. 5. FIG. 9 is a circuit diagram for explaining an anode holding operation performed by the pixel PX in a fourth period P4 of FIG. 5. FIG. 10 is a circuit diagram for explaining a light-emitting operation performed by the pixel PX in a fifth period P5 of FIG. 5. That is, the operation periods of the pixel PX may include the first period P1 in which the anode initialization operation is performed, the second period P2 in which the gate initialization operation is performed, the third period P3 in which the data writing operation and the threshold voltage compensation operation are performed, the fourth period P4 in which the anode holding operation is performed, and the fifth period P5 in which the light-emitting operation is performed.

Referring to FIGS. 2 and 5 to 10, the pixel PX may sequentially perform the anode initialization operation, the gate initialization operation, the data writing operation, the threshold voltage compensation operation, the anode holding operation, and the light-emitting operation during one frame. Here, the data writing operation and the threshold voltage compensation operation may be performed in the same operation period. As the pixel PX sequentially performs the anode initialization operation, the gate initialization operation, the data writing operation, the threshold voltage compensation operation, the anode holding operation, and the light-emitting operation during one frame, the operation periods of the pixel PX may sequentially proceed through the first period P1, the second period P2, the third period P3, the fourth period P4, and the fifth period P5.

In cast that a gate signal (or an emission control signal) applied to a gate electrode of a PMOS transistor has a high level (i.e., an inactive level), the PMOS transistor may be turned off. Conversely, in cast that the gate signal (or the emission control signal) applied to the gate electrode of the PMOS transistor has a low level (i.e., an active level), the PMOS transistor may be turned on.

In cast that a gate signal (or an emission control signal) applied to a gate electrode of a NMOS transistor has a high level (i.e., an active level), the PMOS transistor may be turned on. Conversely, in cast that the gate signal (or the emission control signal) applied to the gate electrode of the NMOS transistor has a low level (i.e., an inactive level), the PMOS transistor may be turned off.

In the first period P1, the first gate signal GW may have a high level GW_H, the second gate signal GC may have a high level GC_H, the third gate signal EB may have a high level EB_H, the fourth gate signal GI1 may have a high level GI1_H, the fifth gate signal GI2 may have a low level GI2_L, and the emission control signal EM may have a low level EM_L. That is, in the first period P1, the third gate signal EB, the fourth gate signal GI1, and the emission control signal EM may have active levels, and the first gate signal GW, the second gate signal GC, and the fifth gate signal GI2 may have inactive levels. In this case, the fourth transistor T4, the sixth transistor T6, and the seventh transistor T7 may be turned on, and the second transistor T2 and the third transistor T3 may be turned off.

Accordingly, during the first period P1, the third node N3 may receive the pre-charging voltage VPRE, and the fourth node N4 may receive the initialization voltage VINT. In this case, the voltage of the third node N3 and the voltage of the fourth node N4 may be initialized. In addition, the second node N2 may receive the initialization voltage VINT. In this case, the voltage of the second node N2 may be initialized.

In the second period P2, the first gate signal GW may have the high level GW_H, the second gate signal GC may have the high level GC_H, the third gate signal EB may have the high level EB_H, the fourth gate signal GI1 may have the high level GI1_H, the fifth gate signal GI2 may transition from the high level GI2_H to the low level GI2_L after a predetermined time has elapsed after transitioning from the low level GI2_L to the high level GI2_H, and the light-emission control signal EM may have the high level EM_H. That is, in the second period P2, the third gate signal EB, the fourth gate signal GI1, and the fifth gate signal GI2 may have active levels, and the first gate signal GW, the second gate signal GC, and the emission control signal EM may have inactive levels. In this case, the fifth transistor T5, the sixth transistor T6, and the seventh transistor T7 may be turned on, and the second transistor T2, the third transistor T3, and the fourth transistor T4 may be turned off.

Accordingly, during the second period P2, the first node N1 and the third node N3 may receive the pre-charging voltage VPRE, and the fourth node N4 may receive the initialization voltage VINT. In this case, the voltage of the first node N1, the voltage of the third node N3, and the voltage of the fourth node N4 may be initialized.

In the third period P3, the first gate signal GW may transition from the low level GW_L to the high level GW_H after a predetermined time has elapses after transitioning from the high level GW_H to the low level GW_L, the second gate signal GC may transition from the low level GC_L to the high level GC_H after a predetermined time has elapses after transitioning from the high level GC_H to the low level GC_L, the third gate signal EB may have the high level EB_H, the fourth gate signal GI1 transitions from the high level GI1_H to the low level GI1_L, the fifth gate signal GI2 may have the low level GI2_L, and the emission control signal EM may have the high level EM_H. That is, in the third period P3, the first gate signal GW, the second gate signal GC, and the third gate signal EB may have active levels, and the fourth gate signal GI1, the fifth gate signal GI2, and the emission control signal EM may have inactive levels. In this case, the second transistor T2, the third transistor T3, and the fifth transistor T5 may be turned on, and the fourth transistor T4, the sixth transistor T6, and the seventh transistor T7 may be turned off.

Accordingly, during the third period P3, the third node N3 may receive the data voltage VDATA, the fourth node N4 may receive the initialization voltage VINT, and the third transistor T3 may diode-connect the first transistor T1. In this case, the voltage of the fourth node N4 may be initialized. In addition, the voltage of the third node N3 may become the value of the data voltage VDATA, and the voltage of the first node N1 may be a value obtained by subtracting the absolute value of the threshold voltage (Vth) of the first transistor T1 from the first power voltage ELVDD. Here, the data voltage VDATA may have a level corresponding to a predetermined grayscale.

In the fourth period P4, the first gate signal GW may have the high level GW_H, the second gate signal GC may have the high level GC_H, the third gate signal EB may have the high level EB_H, the fourth gate signal GI1 may have the high level GI1_H, the fifth gate signal GI2 may have the low level GI2_L, and the emission control signal EM may have the low level EM_L. That is, in the fourth period P4, the third gate signal EB, the fourth gate signal GI1, and the emission control signal EM may have active levels, and the first gate signal GW, the second gate signal GC, and the fifth gate signal GI2 may have inactive levels. In this case, the fourth transistor T4, the fifth transistor T5, and the sixth transistor T6 may be turned on, and the second transistor T2, the third transistor T3, and the seventh transistor T7 may be turned off.

Accordingly, during the fourth period P4, the third node N3 may receive the pre-charging voltage VPRE. In this case, the voltage of the third node N3 may be initialized. At the same time, a current path connected to a ground may be formed through the first transistor T1, the fourth transistor T4, and the fifth transistor T5. Due to the current flowing through the current path, a parasitic capacitor may be discharged. In this case, the voltage of the third node N3 may become the value of the pre-charging voltage VPRE, and the voltage of the first node N1 may be determined by the following Equation 1.

$$VN 1 = ELVDD + ( VPRE - VDATA ) - \vert Vth \vert \qquad [ Equation 1 ]$$

Here, VN1 is a voltage of the first node N1.

In the fifth period P5, the first gate signal GW may have the high level GW_H, the second gate signal GC may have the high level GC_H, the third gate signal EB may have the low level EB_L, the fourth gate signal GI1 may have the high level GI1_H, the fifth gate signal GI2 may have the low level GI2_L, and the emission control signal EM may have the low level EM_L. That is, in the fifth period P5, the fourth gate signal GI1 and the emission control signal EM may have active levels, and the first gate signal GW, the second gate signal GC, the third gate signal EB, and the fifth gate signal GI2 may have inactive levels. In this case, the fourth transistor T4 and the sixth transistor T6 may be turned on, and the second transistor T2, the third transistor T3, the fifth transistor T5, and the seventh transistor T7 may be turned off.

Accordingly, during the fifth period P5, the third node N3 may receive the pre-charging voltage VPRE. In this case, the voltage of the third node N3 may be initialized. At the same time, a driving current ID generated by the first transistor T1 may flow through the light-emitting element LED. The driving current ID may be determined by the voltage of the first node N1. Accordingly, the light-emitting element LED may emit light based on the driving current ID. As such, the fifth period P5 may be the light-emitting period in which the light-emitting operation for the light-emitting element LED is performed.

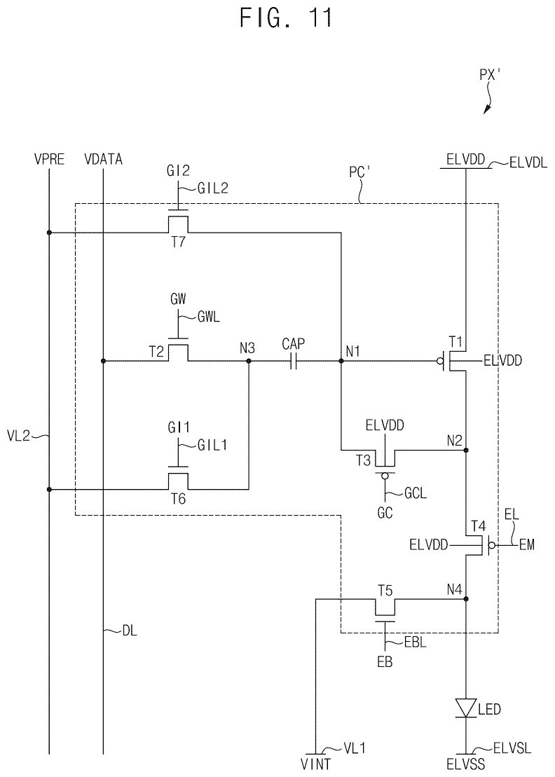

FIG. 11 is a circuit diagram illustrating another example of the circuit structure of one pixel of FIG. 1.

Referring to FIG. 11, one pixel PX′ may include a pixel driving circuit part PC′ and a light-emitting element LED electrically connected to the pixel driving circuit part PC′. The pixel driving circuit part PC′ may generate a driving current, and the light-emitting element LED may generate light based on the driving current. However, the circuit structure of the pixel PX′ described with reference to FIG. 11 may be substantially the same as or similar to the circuit structure of the pixel PX described with reference to FIG. 2, except for the second transistor T2. Hereinafter, redundant descriptions will be omitted or simplified.

In an embodiment, the pixel driving circuit part PC′ may include a first transistor T1, a second transistor T2, a third transistor T3, a fourth transistor T4, a fifth transistor T5, a sixth transistor T6, a seventh transistor T7, and a capacitor CAP.

In an embodiment, the first transistor T1, the third transistor T3, and the fourth transistor T4 may be PMOS transistors, and the second transistor T2, the fifth transistor T5, the sixth transistor T6, and the seventh transistor T7 may be NMOS transistors.

In an embodiment, the first transistor T1, the third transistor T3, and the fourth transistor T4 may be MOSFETs formed by a semiconductor process. That is, the first transistor T1, the third transistor T3, and the fourth transistor T4 may be formed in and on a silicon wafer substrate. In addition, in an embodiment, the second transistor T2, the fifth transistor T5, the sixth transistor T6, and the seventh transistor T7 may be formed of an oxide semiconductor.

The second transistor T2 may include a gate electrode, a first electrode, and a second electrode. The first gate line GWL which receives the first gate signal GW may be connected to the gate electrode of the second transistor T2. The data line DL which receives the data voltage VDATA may be connected to the first electrode of the second transistor T2. The second electrode of the second transistor T2 may be connected to the third node N3.

The second transistor T2 may be turned on or off in response to the first gate signal GW. For example, in case the first gate signal GW has an active level, the second transistor T2 may be turned on. In this case, the second transistor T2 may provide the data voltage VDATA to the third node N3. Conversely, in case the first gate signal GW has an inactive level, the second transistor T2 may be turned off. In this case, the second transistor T2 may block the supply of the data voltage VDATA.

The first transistor T1, the third transistor T3, the fourth transistor T4, the fifth transistor T5, the sixth transistor T6, the seventh transistor T7, and the capacitor CAP of FIG. 11 may be the same as the first transistor T1, the third transistor T3, the fourth transistor T4, the fifth transistor T5, the sixth transistor T6, the seventh transistor T7, and the capacitor CAP of FIG. 2, respectively.

Although FIG. 11 illustrates the pixel driving circuit part PC′ including seven transistors and one capacitor, the embodiments of the present disclosure are not necessarily limited thereto.

In an embodiment, the first transistor T1, the third transistor T3, and the fourth transistor T4 of FIG. 11 may correspond to the first transistor TR1 of FIG. 4, and the second transistor T2, the fifth transistor T5, the sixth transistor T6, and the seventh transistor T7 of FIG. 11 may correspond to the second transistor TR2 of FIG. 4.

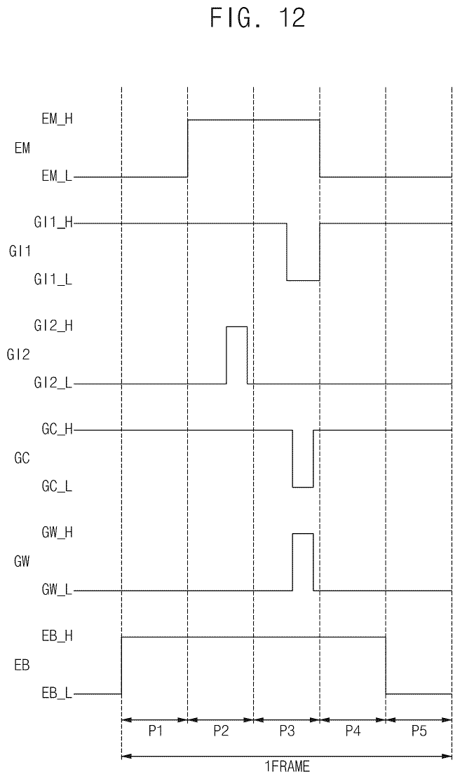

FIG. 12 is a waveform diagram for explaining an operation of the pixel of FIG. 11.

Referring to FIGS. 11 and 12, the pixel PX′ may sequentially perform an anode initialization operation, a gate initialization operation, a data writing operation, a threshold voltage compensation operation, an anode holding operation, and a light-emitting operation during one frame. In this case, the data writing operation and the threshold voltage compensation operation may be performed in the same operation period. As the pixel PX′ sequentially performs the anode initialization operation, the gate initialization operation, the data writing operation, the threshold voltage compensation operation, the anode holding operation, and the light-emitting operation during one frame, the operation periods of the pixel PX′ may also sequentially proceed through the first period P1, the second period P2, the third period P3, the fourth period P4, and the fifth period P5.

However, the operation of the pixel PX′ described with reference to FIG. 12 may be substantially the same as or similar to the operation of the pixel PX described with reference to FIG. 5, except for the waveform of the first gate signal GW. Hereinafter, redundant descriptions will be omitted or simplified.

In the first period P1, the second period P2, the fourth period P4, and the fifth period P5, the first gate signal GW may have the low level GW_L. That is, in the first period P1, the second period P2, the fourth period P4, and the fifth period P5, the first gate signal GW may have an inactive level. In this case, the second transistor T2 may be turned off.

In the third period P3, the first gate signal GW may have the high level GW_H. That is, in the third period P3, the first gate signal GW may have an active level. In this case, the second transistor T2 may be turned on.

The operation of the pixel PX′ in the first period P1, the second period P2, the third period P3, the fourth period P4, and the fifth period P5 may be the same as that described with reference to FIG. 5.

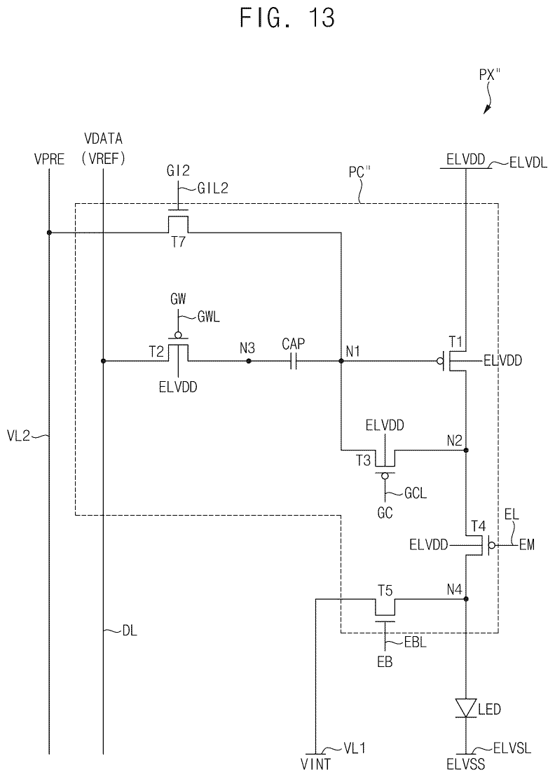

FIG. 13 is a circuit diagram illustrating another example of the circuit structure of one pixel of FIG. 1.

Referring to FIG. 13, one pixel PX″ may include a pixel driving circuit part PC″ and a light-emitting element LED electrically connected to the pixel driving circuit part PC″. The pixel driving circuit part PC″ may generate a driving current, and the light-emitting element LED may generate light based on the driving current. However, the circuit structure of the pixel PX″ described with reference to FIG. 13 may be substantially the same as or similar to the circuit structure of the pixel PX described with reference to FIG. 2, except for the second transistor T2 and the sixth transistor T6. Hereinafter, redundant descriptions will be omitted or simplified.

In an embodiment, the pixel driving circuit part PC″ may include a first transistor T1, a second transistor T2, a third transistor T3, a fourth transistor T4, a fifth transistor T5, a seventh transistor T7, and a capacitor CAP. That is, compared to the pixel driving circuit part PC of FIG. 2, the pixel driving circuit part PC″ may omit the sixth transistor T6.

In an embodiment, the first transistor T1, the second transistor T2, the third transistor T3, and the fourth transistor T4 may be PMOS transistors, and the fifth transistor T5 and the seventh transistor T7 may be NMOS transistors.

In an embodiment, the first transistor T1, the second transistor T2, the third transistor T3, and the fourth transistor T4 may be MOSFETs formed by a semiconductor process. That is, the first transistor T1, the second transistor T2, the third transistor T3, and the fourth transistor T4 may be formed in and on a silicon wafer substrate.

In an embodiment, the fifth transistor T5 and the seventh transistor T7 may be formed of oxide semiconductors.

The second transistor T2 may include a gate electrode, a first electrode, and a second electrode. The gate electrode of the second transistor T2 may be connected to the first gate line GWL which receives the first gate signal GW. The first electrode of the second transistor T2 may be connected to the data line DL which receives the data voltage VDATA or a reference voltage VREF. The second electrode of the second transistor T2 may be connected to the third node N3. For example, the reference voltage VREF may have a voltage level lower than the data voltage VDATA.

The second transistor T2 may further include a body electrode. The body electrode of the second transistor T2 may receive the first power voltage ELVDD. For example, the body electrode of the second transistor T2 may be connected to a first power line ELVDL receiving the first power voltage ELVDD. Alternatively, a power voltage other than the first power voltage ELVDD may be applied to the body electrode of the second transistor T2.

The second transistor T2 may be turned on or off in response to the first gate signal GW. For example, in case the first gate signal GW has an active level, the second transistor T2 may be turned on. In this case, the second transistor T2 may supply the data voltage VDATA or the reference voltage VREF to the third node N3. Conversely, in case the first gate signal GW has an inactive level, the second transistor T2 may be turned off. In this case, the second transistor T2 may block the supply of the data voltage VDATA and the reference voltage VREF.

The second transistor T2 may perform the role of the sixth transistor T6 of FIG. 2. That is, the second transistor T2 may provide the reference voltage VREF to the third node N3 to initialize the voltage of the third node N3.

The first transistor T1, the third transistor T3, the fourth transistor T4, the fifth transistor T5, the seventh transistor T7, and the capacitor CAP of FIG. 13 may be the same as the first transistor T1, the third transistor T3, the fourth transistor T4, the fifth transistor T5, the seventh transistor T7, and the capacitor CAP of FIG. 2, respectively.

Although FIG. 13 illustrates that the pixel driving circuit part PC″ includes six transistors and one capacitor, the embodiments of the present disclosure are not necessarily limited thereto.

In an embodiment, the first transistor T1, the second transistor T2, the third transistor T3, and the fourth transistor T4 of FIG. 13 may correspond to the first transistor TR1 of FIG. 4, and the fifth transistor T5 and the seventh transistor T7 of FIG. 13 may correspond to the second transistor TR2 of FIG. 4.

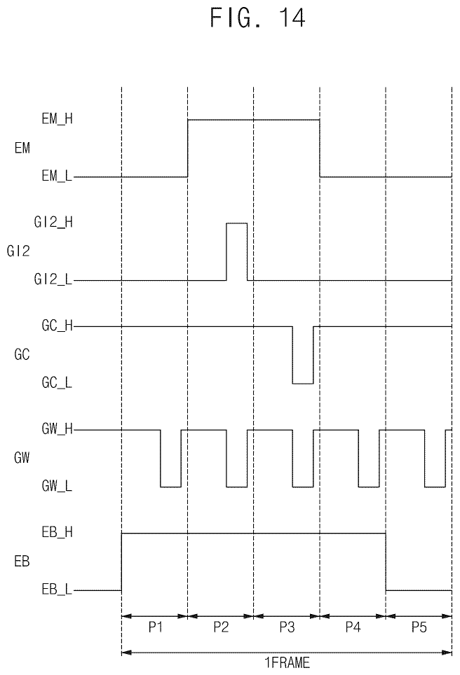

FIG. 14 is a waveform diagram for explaining an operation of the pixel of FIG. 13.

Referring to FIGS. 13 and 14, the pixel PX″ may sequentially perform an anode initialization operation, a gate initialization operation, a data writing operation, a threshold voltage compensation operation, an anode holding operation, and a light-emitting operation during one frame. In this case, the data writing operation and the threshold voltage compensation operation may be performed in the same operation period. As the pixel PX″ sequentially performs the anode initialization operation, the gate initialization operation, the data writing operation, the threshold voltage compensation operation, the anode holding operation, and the light-emitting operation during one frame, the operation periods of the pixel PX″ may also sequentially proceed through the first period P1, the second period P2, the third period P3, the fourth period P4, and the fifth period P5.

However, the operation of the pixel PX″ described with reference to FIG. 14 may be substantially the same as or similar to the operation of the pixel PX described with reference to FIG. 5, except for the waveform shape of the first gate signal GW and the omission of the fourth gate signal GI1. Hereinafter, redundant descriptions will be omitted or simplified.

In the first period P1, the second period P2, the third period P3, the fourth period P4, and the fifth period P5, the first gate signal GW may transition from the high level GW_H to the low level GW_L after a predetermined time has elapsed. That is, in the first period P1, the second period P2, the third period P3, the fourth period P4, and the fifth period P5, the first gate signal GW may have an active level. In this case, the second transistor T2 may be turned on.

Accordingly, during the first period P1, the second period P2, the fourth period P4, and the fifth period P5, the third node N3 may receive the reference voltage VREF. In this case, the voltage of the third node N3 may be initialized. In addition, during the third period P3, the third node N3 may receive the data voltage VDATA. Here, the data voltage VDATA may have a level corresponding to a predetermined grayscale.

The operation of the pixel PX″ in the first period P1, the second period P2, the third period P3, the fourth period P4, and the fifth period P5 may be the same as described with reference to FIG. 5, except for the omission of the fourth gate signal GI1.

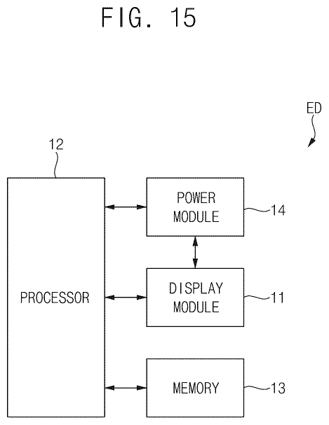

FIG. 15 is a block diagram illustrating an electronic device according to embodiments of the present disclosure.

Referring to FIG. 15, an electronic device 10 according to embodiments of the present disclosure may include a display module 11, a processor 12, a memory 13, and a power module 14.

A display device (e.g., the display device DD of FIG. 1) according to embodiments of the present disclosure may be applied to various electronic devices. The electronic device 10 may include the display device described above, and may further include a module or device having additional functions in addition to the display device.

The processor 12 may include at least one of a central processing unit (CPU), an application processor (AP), a graphic processing unit (GPU), a communication processor (CP), and an image signal processor (ISP).

The memory 13 may store data information for the operation of the processor 12 or the display module 11. In case the processor 12 executes the application stored in the memory 13, an input image data (e.g., IDAT of FIG. 1) and/or a control signal (e.g., CTRL of FIG. 1) may be transmitted to the display module 11, and the display module 11 may process the received signal and output image information through a display screen.

The power module 14 may include a power supply module which supplies external power, such as a power adapter or a battery device, and a power conversion module which converts the external power supplied by the power supply module to generate power voltage (e.g., ELVDD and ELVSS of FIGS. 1 and 2) for the operation of the electronic device 10.

At least one of each component of the electronic device 10 described above may be included in the display device according to the above-described embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

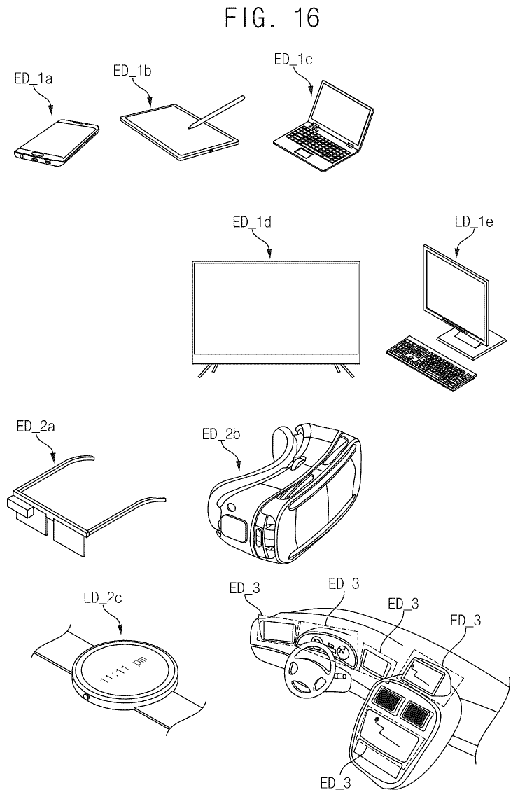

FIG. 16 is a schematic diagram illustrating an electronic device according to various embodiments.

Referring to FIGS. 15 and 16, various electronic devices ED to which display devices according to the embodiments are applied may include not only image display electronic devices such as a smartphone ED_1a, a tablet PC ED_1b, a laptop ED_1c, a TV ED_1d, and a desktop monitor ED_1e, but also wearable electronic devices including display modules, such as smart glasses ED_2a, a head-mounted display ED_2b, and a smart watch ED_2c, automotive electronic devices ED_3 including display modules, such as a dashboard of a car, a center fascia, a Center Information Display (CID) disposed on a dashboard, and a room mirror display, or the like.

As described above, while the present disclosure has been explained with reference to embodiments, it will be understood by those of ordinary skill in the art that various modifications and changes can be made thereto without departing from the spirit and scope of the present disclosure as defined in the following claims.

The present disclosure may be applied to various display device which can be equipped with a display device. For example, the present disclosure may be applied to high-resolution smartphones, mobile phones, smart pads, smart watches, tablet PCs, vehicle navigation systems, televisions, computer monitors, and notebook computers.

What is claimed is:

1. A display panel comprising:
a circuit layer including a pixel driving circuit part including:
a first transistor including a gate electrode connected to a first node, a first electrode which receives a first power voltage, and a second electrode connected to a second node;
a second transistor including a gate electrode which receives a first gate signal, a first electrode which receives a date voltage, and a second electrode connected to a third node;
a third transistor including a gate electrode which receives a second gate signal, a first electrode connected to the first node, and a second electrode connected to the second node;
a fourth transistor including a gate electrode which receives an emission control signal, a first electrode connected to the second node, and a second electrode connected to a fourth node;
a first initialization transistor, which is an N-channel Metal-Oxide-Semiconductor (NMOS) transistor, includes a gate electrode which receives a first initialization gate signal, a first electrode which receives an initialization voltage, and a second electrode connected to the fourth node;
a second initialization transistor, which is an NMOS transistor, includes a gate electrode which receives a second initialization gate signal, a first electrode which receives a pre-charging voltage, and a second electrode connected to the first node; and
a capacitor connected between the third node and the first node; and
a light-emitting element disposed on the circuit layer and including an anode electrode connected to the fourth node and a cathode electrode which receives a second power voltage.

2. The display panel of claim 1, wherein the circuit layer further includes a first insulating layer disposed on a silicon wafer substrate and a second insulating layer disposed on the first insulating layer,
wherein the first transistor, the second transistor, the third transistor, and the fourth transistor are disposed in and on the silicon wafer substrate, and
wherein the first initialization transistor and the second initialization transistor are disposed on the first insulating layer.

3. The display panel of claim 1, wherein the NMOS transistors of the first initialization transistor and the second initialization transistor includes oxide semiconductors.

4. The display panel of claim 1, wherein the first transistor, the second transistor, the third transistor, and the fourth transistor are P-channel Metal-Oxide-Semiconductor (PMOS) transistors.

5. The display panel of claim 4, wherein the PMOS transistors of the first transistor, the second transistor, the third transistor, and the fourth transistor are disposed in and on a silicon wafer substrate.

6. The display panel of claim 1, wherein the pixel driving circuit part further includes:
a third initialization transistor including a gate electrode which receives a third initialization gate signal, a first electrode which receives the pre-charging voltage, and a second electrode connected to the third node.

7. The display panel of claim 6, wherein the third initialization transistor is an NMOS transistor including an oxide semiconductor.

8. The display panel of claim 6, wherein the pixel driving circuit part and the light-emitting element constitute a pixel which sequentially performs an anode initialization operation, a gate initialization operation, a data writing operation, a threshold voltage compensation operation, an anode holding operation, and a light-emitting operation, and
wherein the data writing operation and the threshold voltage compensation operation are performed in a same operation period.

9. The display panel of claim 8, wherein in a first period where the anode initialization operation is performed, the first gate signal, the second gate signal, and the second initialization gate signal have inactive levels, and the first initialization gate signal, the third initialization gate signal, and the emission control signal have active levels,
wherein in a second period where the gate initialization operation is performed, the first gate signal, the second gate signal, and the emission control signal have inactive levels, and the first initialization gate signal, the second initialization gate signal, and third initialization gate signal have active levels, and
wherein in a third period where the data writing operation and the threshold voltage compensation operation are performed, the second initialization gate signal, the third initialization gate signal, and the emission control signal have inactive levels, and the first gate signal, the second gate signal, and the first initialization gate signal have active levels.

10. The display panel of claim 9, wherein in a fourth period where the anode holding operation is performed, the first gate signal, the second gate signal, and the second initialization gate signal have inactive levels, and the first initialization gate signal, the third initialization gate signal, and the emission control signal have active levels, and
wherein in a fifth period where the light-emitting operation is performed, the first gate signal, the second gate signal, the first initialization gate signal, and the second initialization gate signal have inactive levels, and the third initialization gate signal and the emission control signal have active levels.

11. The display panel of claim 1, wherein the first transistor, the third transistor, and the fourth transistor are PMOS transistor disposed in and on a silicon wafer substrate, and the second transistor is an NMOS transistor including an oxide semiconductor.

12. The display panel of claim 1, wherein the second transistor is configured to receive the date voltage or a reference voltage.

13. The display panel of claim 12, wherein the pixel driving circuit part and the light-emitting element constitute a pixel which sequentially performs an anode initialization operation, a gate initialization operation, a data writing operation, a threshold voltage compensation operation, an anode holding operation, and a light-emitting operation, and
the data writing operation and the threshold voltage compensation operation are performed in a same operation period,
wherein in a first period where the anode initialization operation is performed, the second gate signal, and the second initialization gate signal have inactive levels, and the first initialization gate signal, the first gate signal, and the emission control signal have active levels,
wherein in a second period where the gate initialization operation is performed, the second gate signal, and the emission control signal have inactive levels, and first gate signal, the first initialization gate signal and the second initialization gate signal have active levels, and
wherein in a third period where the data writing operation and the threshold voltage compensation operation are performed, the second initialization gate signal and the emission control signal have inactive levels, and the first gate signal, the second gate signal, and the first initialization gate signal have active levels.

14. The display device of claim 13, wherein in a fourth period where the anode holding operation is performed, the second gate signal, and the second initialization gate signal have inactive levels, and the first gate signal, the first initialization gate signal and the emission control signal have active levels, and
wherein in a fifth period where the light-emitting operation is performed, the second gate signal, the first initialization gate signal, and the second initialization gate signal have inactive levels, and the first gate signal, and the emission control signal have active levels.

15. The display device of claim 14, wherein in the first period, the second period, the fourth period, and the fifth period, the third node receives the reference voltage, and
wherein in the third period, the third node receives the date voltage.

16. An electronic device comprising:
a display device including:
a display panel including: a circuit layer including a pixel driving circuit part and a light-emitting element disposed on the circuit layer and electrically connected to the pixel driving circuit part;
a date driver which provides a data voltage to the display panel;
a gate driver which provides gate signals to the display panel;
an emission driver which provides an emission control signal to the display panel; and
a controller which controls the data driver, the gate drive, and the emission driver based on an input image data and a control signal; and
a processor which provides the input image data and the control signal to the controller,
wherein the pixel driving circuit part includes:
a first transistor including a gate electrode connected to a first node, a first electrode which receives a first power voltage, and a second electrode connected to a second node;
a second transistor including a gate electrode which receives a first gate signal, a first electrode which receives the date voltage, and a second electrode connected to a third node;
a third transistor including a gate electrode which receives a second gate signal, a first electrode connected to the first node, and a second electrode connected to the second node;
a fourth transistor including a gate electrode which receives the emission control signal, a first electrode connected to the second node, and a second electrode connected to a fourth node;
a first initialization transistor, which is an NMOS transistor, includes a gate electrode which receives a first initialization gate signal, a first electrode which receives an initialization voltage, and a second electrode connected to the fourth node;
a second initialization transistor, which is an NMOS transistor, includes a gate electrode which receives a second initialization gate signal, a first electrode which receives a pre-charging voltage, and a second electrode connected to the first node; and
a capacitor connected between the third node and the first node, and
wherein the light-emitting element includes an anode electrode connected to the fourth node and a cathode electrode which receives a second power voltage.

17. The electronic device of claim 16, wherein the circuit layer further includes a first insulating layer disposed on a silicon wafer substrate and a second insulating layer disposed on the first insulating layer,
wherein the first transistor, the second transistor, the third transistor, and the fourth transistor are disposed in and on the silicon wafer substrate, and
wherein the first initialization transistor and the second initialization transistor are disposed on the first insulating layer.

18. The electronic device of claim 16, wherein the NMOS transistors of the first initialization transistor and the second initialization transistor includes oxide semiconductors.

19. The electronic device of claim 16, wherein the first transistor, the second transistor, the third transistor, and the fourth transistor are PMOS transistors.

20. The electronic device of claim 16, wherein the pixel driving circuit part further includes:
a third initialization transistor including a gate electrode which receives a third initialization gate signal, a first electrode which receives the pre-charging voltage, and a second electrode connected to the third node, and
wherein the third initialization transistor is an NMOS transistor including an oxide semiconductor.
